(19) United States
(12) Patent Application Publication
(10) Pub. No.: US 2011/0176694 A1
(43) Pub. Date: Jul. 21, 2011

(54) Multi-port combiner for an audio amplifier

(76) Inventor: Thomas H. Schurr, Copley, OH (US)

(21) Appl. No.: 12/930,641

(22) Filed: Jan. 10, 2011

Related U.S. Application Data
(60) Provisional application No. 61/294,826, filed on Jan. 13, 2010.

(51) Int. Cl. H03F 99/00

(52) U.S. Cl. 381/120

(57) ABSTRACT

A multi-port combiner for an audio amplifier is configured with a plurality of series-parallel coupled connection ports to enable one or more speaker monitors coupled thereto to receive audio signals from a single output port of the amplifier. The multi-port combiner also includes a phantom load having an impedance that is equivalent to that of one of the speaker monitors. As such, the phantom load is selectively coupled to the connection ports to maintain the series-parallel configuration of the connection ports, so that the equivalent impedance of all the speaker monitors coupled to the multi-port combiner is maintained within an acceptable operating range established by the amplifier.

### CROSS-REFERENCE TO RELATED APPLICATION

This application claims the benefit of U.S. Provisional Application No. 61/294,826 filed Jan. 13, 2010, the content of which is incorporated herein by reference.

### TECHNICAL FIELD

The present invention generally relates to audio amplifiers for use with multiple speaker monitors. Particularly, the present invention relates to a multi-port combiner that enables multiple speaker monitors to be coupled together to a single output port of an audio amplifier, while providing an equivalent impedance that is within the amplifier's operating range.

### BACKGROUND OF THE INVENTION

Musicians who are performing at a venue where they have difficulty hearing themselves typically use an amplifier coupled to one or more stage monitors or speaker monitors. Such monitors include any suitable audio speaker, and are positioned on stage so that they are directed at the musical performers or musicians, rather than the audience. As such, the speaker monitors provide a desired level of audio feedback to the performers so that they can hear themselves during a performance. To accomplish this, the venue typically provides a mixing board and other associated equipment that amplifies and processes the sound signals received from the performers' microphones so that they can be delivered to as many speaker monitors as the performers need.

Unfortunately, such equipment is expensive, and musicians who do not have access to such equipment generally utilize an audio stage amplifier, such as a 2-channel powered mixer, which typically is designed to power a speaker monitor having an impedance load that is in the range of 4 to 8 Ohms. Due to the nature of impedances, the net or equivalent impedance for series-coupled speaker monitors is additive, while the impedance of parallel-coupled speaker monitors is divided among parallel-connected speakers, whereby the equivalent impedance is established by calculated by dividing the product of the impedances by the sum of the impedances (or dividing 1 by the sum of the inverses of the impedances).

Thus, because a typical speaker monitor comprises an impedance load of 8 Ohms, two 8 Ohm speaker monitors can be coupled in parallel, which due to the nature of impedances, yields a 4 Ohm net impedance load, which is still within the acceptable impedance range that a typical amplifier output is capable of handling. As such, a typical audio amplifier will be able to produce acceptable sound quality and volume for either a single speaker monitor (8 Ohm load) or for two speaker monitors placed in a parallel connection (4 Ohm load). However, many musical groups that include multiple musicians require more than two speaker monitors. Unfortunately, utilizing more than two speaker monitors will yield a net or equivalent impedance that exceeds the amplifier's acceptable operating range of 4 to 8 Ohms, causing it to be overloaded. For example, coupling four 8 Ohm speaker monitors in parallel will present a load of only 2 Ohms to the amplifier, which is below the amplifier's output impedance of 4 to 8 Ohms, resulting in excess current being drawn through the amplifier. As a result, utilizing more than two speaker monitors causes the amplifier to generate distorted audio with reduced volume levels, while causing the amplifier to overheat, resulting in shortened amplifier life and possibly permanent damage.

Therefore, there is a need for a multi-port combiner for an audio amplifier that is configured to allow multiple speaker monitors having an impedance of 1-8 Ohms to be coupled to a single output line of an amplifier without exceeding the impedance range of the amplifier causing it to be overloaded. Furthermore, there is a need for a multi-port combiner that utilizes a phantom load to transform the impedances of multiple speaker monitors into an equivalent impedance that is within the operating range of a single output port provided by the amplifier.

### SUMMARY OF THE INVENTION

In light of the foregoing, it is a first aspect of the present invention to provide a multi-port combiner for coupling at least one speaker monitor to an output port of an amplifier including a first, second, third, fourth, fifth, and sixth connection port. The second, fourth, and sixth connection ports are coupled in parallel between a first and a second node. The first, third, and fifth connection ports are coupled in parallel between said second node and a third node. Each speaker monitor is coupled sequentially to a corresponding connection port. A first input terminal is coupled at one end to the first node, and a second input terminal is coupled at one end to the third node. The other ends of the first and second input terminals are adapted to be coupled to the output port of the amplifier to receive signals therefrom. A switch and a phantom load are coupled between the first and second nodes, such that when the switch is in a first state, said phantom load is active, and when the switch is in a second state, the phantom load is inactive.

It is another aspect of the present invention to provide a multi-port combiner for coupling at least one speaker monitor to an output port of an amplifier including a first, second, third, fourth, fifth, sixth, seventh, and eighth connection port. The third, fourth, sixth, and eighth connection ports are coupled in parallel between a first node and a second node, and said first, second, fifth, and seventh connection ports are coupled in parallel between the second node and a third node. Each speaker monitor is sequentially coupled to a corresponding said connection port. A first connection terminal is coupled at one end to a first node, and a second input terminal is coupled at one end to a third node. The other ends of the first and second input terminals are adapted to be coupled to the output port of the amplifier to receive signals therefrom. A switch and a phantom load are coupled between the first and second nodes, such that when the switch is in a first state, the first and second nodes are connected, when the switch is in a second state, the second node is floating, and when the switch is in a third state, the phantom load is active.

### BRIEF DESCRIPTION OF THE DRAWINGS

FIG. 1 is a schematic diagram of a multi-port combiner for an audio amplifier in accordance with the concepts of the present invention; and

FIG. 2 is a schematic diagram of an alternative embodiment of a multi-port combiner for an audio amplifier in accordance with the concepts of the present invention.

### DETAILED DESCRIPTION OF THE INVENTION

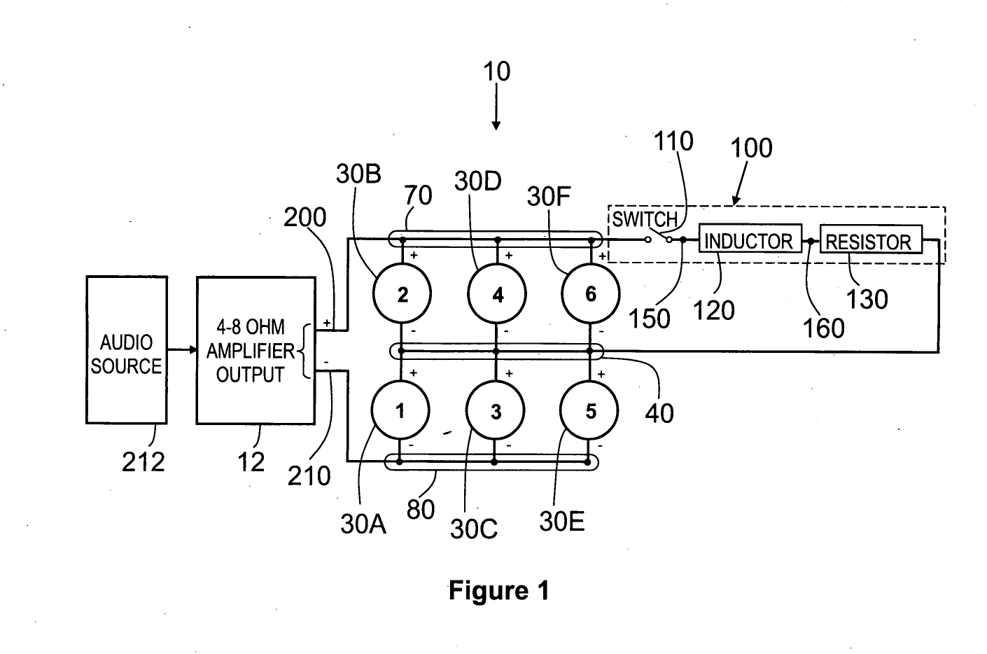

A multi-port combiner is generally indicated by the numeral 10, as shown in FIG. 1 of the drawings. The multi-port combiner 10 is configured to enable multiple, 8 Ohm speaker monitors to be connected in a series-parallel combination, such that their combined equivalent impedance is maintained within a 4 to 8 Ohm range that is required by an audio amplifier 12 to which the speaker monitors are coupled. As a result, the amplified audio signals are allowed to be delivered evenly and in phase to each speaker monitor, without distortion, and with full or increased power. While the combiner 10 is discussed for use with speaker monitors having an impedance of 4 to 8 Ohms, it should be appreciated that the combiner 10 may be configured for use with other impedance magnitudes depending on the operating impedance range of the amplifier 12 being used.

In one aspect, as shown in FIG. 1, the multi-port combiner 10 includes six output jacks or connection ports 30A-F, with each port having positive and negative terminals. It should be appreciated that the connection ports 30 may consist of any electronic jack or port that is configured to carry audio signals to one or more speaker monitors that are coupled thereto. It should be appreciated that the connection ports 30 may include any suitable connector that is capable of carrying audio signals, such as a “SpeakOn” type connector or audio jack. Thus, the negative terminal of connection port 30B is coupled in series with the positive terminal of connection port 30A at a node 40; the negative terminal of connection port 30D is coupled in series with the positive terminal of connection port 30C at node 40; and the negative terminal of connection port 30F is coupled in series with the positive terminal of connection port 30E at node 40. In addition, the positive terminals of the connection ports 30B, 30D, and 30F are coupled together at node 70, while the negative terminals of the connection ports 30A, 30C, and 30E are coupled together at node 80. As such, the connection ports 30A-F are coupled in a series-parallel configuration, such that connection ports 30B, 30D, and 30F are coupled in parallel with each other between nodes 40 and 70; connection ports 30A, 30C, and 30E are coupled in parallel with each other between nodes 40 and 80; and connection ports 30A and 30B, 30C and 30D, and 30E and 30F are coupled in series at node 40.

Coupled between nodes 40 and 70, so as to be in parallel with connection ports 30B, 30D, and 30F, is a phantom impedance or phantom load 100, which includes a series coupled switch 110, inductor 120, and resistor 130. As such, one terminal of the switch 110 is coupled to node 70, while the other terminal of the switch is coupled to the inductor at node 150. To complete the phantom load or impedance 100, one terminal of the resistor 130 is coupled to node 40, and the other terminal is coupled to the inductor 120 at node 160. In one aspect, the switch 110 may include a single pole, single throw switch, such as a slide or rocking toggle switch, while the inductor 120 may have an inductance of 860 μH, rated at 3 amps, and the resistor 130 may comprise a 6 Ohm non-inductive resistor. While the operating values and/or specifications associated with the inductor 120 and resistor 130 are chosen so that they establish an equivalent impedance that approximates the nominal impedance of an actual speaker monitor that would be typically coupled to one of the connection ports 30 of the multi-port combiner 10 (such as a 4 to 8 Ohm speaker monitor), it should be appreciated that the inductor 120 and the resistor 130 may be selected with different operating values and ratings to better match the specific impedance load of the speaker monitors used with the multi-port combiner 10. Moreover, the resistor 130 may also include any suitable means for dissipating heat therefrom, such as a heat sink or other heat-conducting attachment.

In order to supply audio signals generated by the audio amplifier 12 to the multi-port combiner 10 for delivery to the speaker monitors coupled to the connection ports 30A-F, the multi-port combiner 10 includes input terminals 200 and 210 that are coupled to respective nodes 70 and 80, which are suitable for coupling to a single output port of the audio amplifier 12. It should be appreciated that the amplifier 12 may amplify audio signals received from microphones or any other audio output device or source 212, such as a CD (compact disc) player, DVD (digital video disc), or DAT (digital audio tape) player, for example. It should also be appreciated that the input terminals 200 and 210 may be configured as a connection port having the same structure as connection ports 30A-F, however, the input terminals 200 and 210 may comprise any connector suitable for coupling the combiner 10 to the amplifier 12.

Thus, the multi-port combiner 10 is configured for operation in two configurations; a first configuration in which three or four speaker monitors are used; or a second configuration in which five or six speaker monitors are used. To place the multi-port combiner 10 into operation, the output terminals 200 and 210 are coupled to the audio amplifier 12. Next, various speaker monitors are coupled to the connection ports 30A-F of the multi-port combiner 10 sequentially, whereby the first speaker monitor is coupled to connection port 30A; the second speaker monitor is coupled to connection port 30B; the third speaker monitor is coupled to connection port 30C; the fourth speaker monitor is coupled to connection port 30D; the fifth speaker monitor is coupled to connection port 30E; and the sixth speaker monitor is coupled to connection port 30F.

In the case of operating the multi-port combiner 10 with four or six speaker monitors, the switch 110 is placed in an open state to disable the operation of the phantom load or impedance 100. As such, the multi-port combiner 10 places the speaker monitors coupled to connection ports 30A-D (four speaker monitor configuration) or the speaker monitors coupled to connection ports 30A-F (six speaker monitor configuration) in a series-parallel configuration, as previously discussed.

It should be appreciated that regardless of the state of the switch 110, the combined equivalent impedance of the speaker monitors is maintained within about a 4 to 8 Ohm range that is required by the amplifier 12 to which the speaker monitors are coupled.

However, when three or five speaker monitors are coupled to the connection ports 30A-B or 30A-E, the switch 110 is placed in a closed mode or state, thereby placing the phantom load or impedance 100 across nodes 40 and 70, such that the phantom load or impedance 100 is placed in series with the odd numbered speaker monitor. For example, in the case where three speaker monitors are coupled to the connection ports 30A-C and the switch 110 is closed, the phantom load 100 is placed in parallel with connection port 30B and in series with connection port 30C, so as to maintain the series-parallel configuration previously discussed.

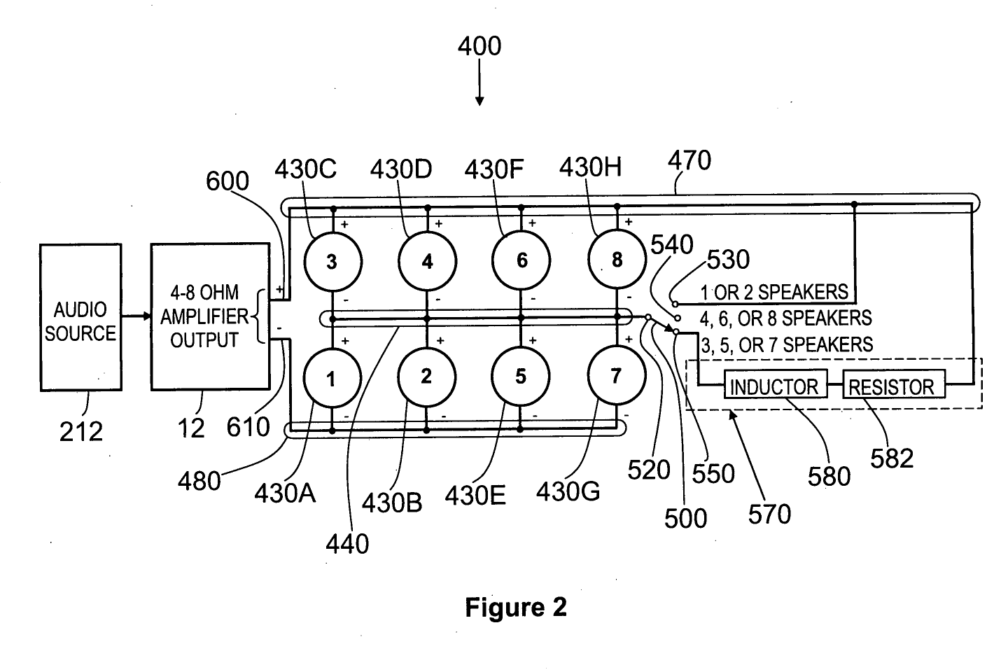

In another embodiment, shown in FIG. 2, a multi-port combiner 400 may be configured to enable one to eight 8 Ohm speaker monitors to be connected in a series-parallel combination, such that their combined equivalent impedance is maintained within about a 4 to 8 Ohm range that is required by the amplifier 12 to which the speaker monitors are coupled, such that power is delivered evenly and in phase to each speaker monitor.

Specifically, the multi-port combiner 400 includes eight output jacks or connection ports 430A-H, with each port having positive and negative terminals. It should be appreciated that the connection ports 430A-H may include any connector that is configured to carry audio signals to one or more speaker monitors that are coupled thereto, such as a “SpeakOn” type connector or other audio jack. Thus, the negative terminal of connection port 430C is coupled in series with the positive terminal of connection port 430A at a node 440; the negative terminal of connection port 430D is coupled in series with the positive terminal of connection port 430B at node 440; the negative terminal of connection port 430F is coupled in series with the positive terminal of connection port 430E at node 440; and the negative terminal of connection port 430H is coupled in series with the positive terminal of connection port 430G at node 440. In addition, the positive terminals of the connection ports 430C, 430D, 430F, and 430H are coupled together at node 470, while the negative terminals of the connection ports 430A, 430B, 430E and 430G are coupled together at node 480. As such, the connection ports 430A-H are coupled in a series-parallel configuration, such that connection ports 430C, 430D, 430F, and 430H are coupled in parallel with each other between nodes 440 and 470, while connection ports 430A, 430B, 430E and 430G are coupled in parallel with each other between nodes 440 and 480. Furthermore, the multi-port combiner 400 is configured such that connection ports 430A and 430C; 430B and 430D; 430E and 430F, and 430G and 430H are coupled in series at node 440.

Coupled between nodes 440 and 470 is a multi-position switch 500. The multi-position switch 500 is configured to selectively connect a first switch terminal 520 that is coupled to node 440 to a second switch terminal 530, a third switch terminal 540, or a fourth switch terminal 550. Specifically, the second switch terminal 530 is coupled directly to node 470, while the third switch terminal 540 is floating and is not connected to any components. Coupled between the fourth switch terminal 550 and node 470 is a phantom load or impedance 570. Specifically, the phantom load 570 includes a series coupled inductor 580 and resistor 582 at one of their ends, while the other end of the inductor 580 is coupled to the fourth terminal 550 and while the other end of the resistor 582 is coupled to node 470.

In one aspect, the inductor 580 may have an inductance of 860 μH, rated at 3 amps, and the resistor 582 may be a 6 Ohm non-inductive resistor. Furthermore, while the operating values and/or specifications associated with the inductor 580 and resistor 582 are chosen so that they establish an equivalent impedance that approximates the nominal impedance of an actual speaker monitor that would typically be coupled to one of the connection ports 430 of the multi-port combiner 400 (such as a 4 to 8 Ohm speaker monitor), it should be appreciated that the inductor 580 and the resistor 582 may be selected with different operating values and ratings to better match the load of the speaker monitors used with the multi-port combiner 400. Moreover, the resistor 582 may also include any suitable means for dissipating heat therefrom, such as a heat sink or other heat-conducting attachment.

In order to supply audio signals generated by the amplifier 12 to the multi-port combiner 400 for delivery to the speaker monitors coupled to the connection ports 430A-H, the multi-port combiner 400 includes input terminals 600 and 610 that are coupled to respective nodes 470 and 480 which are suitable for coupling to a single output port of the amplifier 12. It should be appreciated that the input terminals 600 and 610 may be configured as a connection port having the same structure as connection ports 430A-H, however, the input terminals 600 and 610 may comprise any connector suitable for coupling the combiner 400 to the amplifier 12.

Thus, the multi-port combiner 400 is configured for operation in multiple configurations in which anywhere from one to eight speaker monitors may be utilized. To place the multi-port combiner 400 into operation, the output terminals 600 and 610 are coupled to the amplifier 12. Next, various speaker monitors are coupled to the multi-port combiner 400, such that the speaker monitors are coupled to the connection ports 430A-F of the connection ports 430A-F of the multi-port combiner 400 sequentially, whereby the first speaker monitor is coupled to connection port 430A; the second speaker monitor is coupled to connection port 430B; the third speaker monitor is coupled to connection port 430C; the fourth speaker monitor is coupled to connection port 430D; the fifth speaker monitor is coupled to connection port 430E; the sixth speaker monitor is coupled to connection port 430F; the seventh speaker monitor is coupled to connection port 430G; and the eighth speaker monitor is coupled to connection port 430H.

Thus, to place the multi-port combiner 400 into operation, any number of speaker monitors totaling one to eight may be utilized, as long as the speaker monitors are coupled to the multi-port combiner 400 in sequence, as discussed above. As such, if a user desires to use one or two speaker monitors, they are coupled to connection ports 430A and 430B and the switch 500 is actuated, so as to be placed in a first mode or state, such that the second switch terminal 530 is coupled to the node 440. As a result, node 440 is directly coupled to the input terminal 600, causing connection ports 430C, 430D, 430F, and 430H to be shorted. If an even number of speaker monitors in excess of two is desired to be used, the switch 500 is actuated so as to be placed in a second mode or state, such that the third terminal 540 is coupled to node 440, which results in the speaker monitors being coupled in the series-parallel configuration previously discussed. Finally, if an odd number of speaker monitors in excess of one are desired to be utilized, the switch 500 is actuated, so as to be placed in a third mode or state, such that the fourth terminal 550 is coupled to node 440, such that the phantom load 570 is coupled across nodes 440 and 470, thus maintaining the series-parallel configuration previously discussed. Thus, if three speaker monitors are used, the phantom load 570 is placed in parallel with connection port 430C, if five speaker monitors are used the phantom load 570 is placed in parallel with connection terminal 430D, and if seven speaker monitors are used the phantom load 570 is placed in parallel with connection port 430F. It should be appreciated that regardless of the state of the switch 500, the combined equivalent impedance of the speaker monitors is maintained within about a 4 to 8 Ohm range that is required by the amplifier 12 to which the speaker monitors are coupled.

It should be appreciated that the combiners 10 and 400 may be configured such that the inductor 120, 580 and resistors 130, 582 of respective phantom load/impedances 100 and 570 may be combined into a single element, such as a wire-wound resistor having a suitable inductance and resistance to enable the operation of such combiners. Thus, reducing the number of parts and cost required to assemble the combiners 10 and 400.

It should also be appreciated that the multi-port combiners 10 and 400 may be readily modified using known techniques to scale or extend its ability to combine more than six and eight speaker monitors in a series-parallel configuration, while still providing a level of impedance that is within the acceptable operating range of the amplifier 12.

It is, therefore, evident that one advantage of the present invention is that a multi-port combiner is configured to be utilized with solid state or tube-based amplifiers, allowing the amplifier to run cooler, and to operate safely within its operating specifications, while delivering more volume. In addition, another advantage of the present invention is that the multi-port combiner combines the impedances of multiple speaker monitors into an equivalent impedance that is within the'operating range of a single amplifier output port without requiring any modification to the amplifier or the speaker monitors. Yet another advantage of the present invention is that the multi-port combiner simplifies the otherwise complicated custom wiring process needed to connect multiple speaker monitors in a series-parallel configuration to maintain the impedance seen by the amplifier within the amplifier's acceptable rated output operating range, such as 4 to 8 Ohms. Still another advantage of the present invention is that the multi-port combiner selectively switches a phantom load having an impedance equivalent to that of a typical speaker monitor into a series-parallel configuration with other connection ports to maintain the impedance of the speaker monitors seen by the amplifier within the amplifier's acceptable impedance range.

Although the present invention has been described in considerable detail with reference to certain embodiments, other embodiments are possible. Therefore, the spirit and scope of the appended claims should not be limited to the description of the embodiments contained herein.

What is claimed is:

1. A multi-port combiner for coupling at least one speaker monitor to an output port of an amplifier comprising:
a first, second, third, fourth, fifth, and sixth connection port, said second, fourth, and sixth connection ports being coupled in parallel between a first and a second node, and said first, third, and fifth connection ports being coupled in parallel between said second node and a third node, wherein each speaker monitor is coupled sequentially to a corresponding said connection port;
a first and a second input terminal, said first input terminal being coupled at one end to said first node, and said second input terminal being coupled at one end to said third node, the other ends of said first and second input terminals being adapted to be coupled to the output port of the amplifier to receive signals therefrom; and
a switch and a phantom load coupled between said first and second nodes, such that when said switch is in a first state said phantom load is active, and when said switching circuit is in a second state said phantom load is inactive.

2. The multi-port combiner of claim 1, wherein said phantom load includes a wire-wound resistor.

3. The multi-port combiner of claim 1, wherein said phantom load includes an inductor and a resistor coupled in series.

4. The multi-port combiner of claim 1, wherein the impedance value of said phantom load is approximately equal to the impedance of the at least one of the speaker monitor coupled to said connection ports.

5. A multi-port combiner for coupling at least one speaker monitor to an output port of an amplifier comprising:
a first, second, third, fourth, fifth, sixth, seventh, and eighth connection port, said third, fourth, sixth, and eighth connection ports being coupled in parallel between a first node and a second node, and said first, second, fifth, and seventh connection ports being coupled in parallel between said second node and a third node, each speaker monitor being sequentially coupled to a corresponding said connection port;
a first and a second input terminal, said first connection terminal being coupled at one end to said first node, and said second input terminal being coupled at one end to said third node, and the other ends of said first and second input terminals being adapted to be coupled to the output port of the amplifier to receive signals therefrom; and
a switch and phantom load coupled between said first and second nodes, such that when said switch is in a first state said first and second nodes are connected, when said switch is in a second state, said second node is floating, and when said switch is in a third state said phantom load is active.

6. The multi-port combiner of claim 5, wherein said phantom load includes a wire-wound resistor.

7. The multi-port combiner of claim 5, wherein said phantom load includes a series coupled inductor and resistor.

8. The multi-port combiner of claim 5, wherein the impedance value of said phantom load is approximately equal to the impedance of the at least one of the speaker monitor coupled to said connection ports.
